(19) United States
(12) Patent Application Publication
(10) Pub. No.: US 2005/0116336 A1
(43) Pub. Date: Jun. 2, 2005

(54) Nano-composite materials for thermal management applications

(75) Inventors: Nasreen G. Chopra, Belmont, CA (US); Shilajeet Banerjee, Belmont, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Koila, Inc., Sunnyvale, CA (US)

(21) Appl. No.: 10/944,472

(22) Filed: Sep. 16, 2004

Related U.S. Application Data
(60) Provisional application No. 60/560,180, filed on Apr. 6, 2004.
(60) Provisional application No. 60/544,709, filed on Feb. 13, 2004.
(60) Provisional application No. 60/532,244, filed on Dec. 23, 2003.
(60) Provisional application No. 60/503,591, filed on Sep. 16, 2003.
(60) Provisional application No. 60/503,612, filed on Sep. 16, 2003.
(60) Provisional application No. 60/503,613, filed on Sep. 16, 2003.
(60) Provisional application No. 60/503,638, filed on Sep. 16, 2003.

(51) Int. Cl. H01L 23/34

(52) U.S. Cl. 257/720

(57) ABSTRACT

Nano-composite materials with enhanced thermal performance that can be used for thermal management in a wide range of applications, including heat sinks, device packaging, semiconductor device layers, printed circuit boards and other components of electronic, optical and/or mechanical systems. One type of nano-composite material has a base material and nanostructures (e.g., nanotubes) dispersed in the base material. Another type of nano-composite material has layers of a base material with nanotube films disposed thereon.

### CROSS-REFERENCES TO RELATED APPLICATIONS

This application claims the benefit of the following six provisional U.S. patent applications:
Application No. 60/503,591, filed Sep. 16, 2003, entitled “Nano-Material for System Thermal Management”;
Application No. 60/503,612, filed Sep. 16, 2003, entitled “Oriented Nano-Material for System Thermal Management”;
Application No. 60/503,613, Sep. 16, 2003, entitled “Nano-Material Thermal and Electrical Contact System”;
Application No. 60/532,244, filed Dec. 23, 2003, entitled “Nanotube Augmentation of Heat Exchange Structure”;
Application No. 60/544,709, filed Feb. 13, 2004, entitled “Nano-Material Thermal Management System”; and
Application No. 60/560,180, filed Apr. 6, 2004, entitled “Heat Transfer Structure.”

This application incorporates by reference for all purposes the entire disclosures of the following seven provisional U.S. patent applications:
Application No. 60/503,591, filed Sep. 16, 2003, entitled “Nano-Material for System Thermal Management”;
Application No. 60/503,612, filed Sep. 16, 2003, entitled “Oriented Nano-Material for System Thermal Management”;
Application No. 60/503,638, filed Sep. 16, 2003, entitled “System for Developing Production Nano-Material”;
Application No. 60/503,613, Sep. 16, 2003, entitled “Nano-Material Thermal and Electrical Contact System”;
Application No. 60/532,244, filed Dec. 23, 2003, entitled “Nanotube Augmentation of Heat Exchange Structure”;
Applicatoin No. 60/544,709, filed Feb. 13, 2004, entitled “Nano-Material Thermal Management System”; and
Application No. 60/560,180, filed Apr. 6, 2004, entitled “Heat Transfer Structure.”

The following five regular U.S. patent applications (including this one) are being filed concurrently, and the entire disclosures of the other four are incorporated by reference into this application for all purposes.
application Ser. No. ______, filed Sep. 16, 2004, entitled “Nano-Composite Materials for Thermal Management Applications” (Attorney Docket No. 022353-000110US);
application Ser. No. ______, filed Sep. 16, 2004, entitled “Nanostructure Augmentation of Surfaces for Enhanced Thermal Transfer with Increased Surface Area” (Attorney Docket No. 022353-000210US);
application Ser. No. ______, filed Sep. 16, 2004, entitled “Nanostructure Augmentation of Surfaces for Enhanced Thermal Transfer with Improved Contact” (Attorney Docket No. 022353-000220US);
application Ser. No. ______, filed Sep. 16, 2004, entitled “System and Method for Developing Production Nano-Material” (Attorney Docket No. 022353-000310US); and
application Ser. No. ______, filed Sep. 16, 2004, entitled “Nano-Material Thermal and Electrical Contact System” (Attorney Docket No. 022353-000410US).

### BACKGROUND OF THE INVENTION

The present invention relates in general to thermal management, and in particular to nano-composite materials for thermal management applications.

Electronic devices such as microprocessors generate heat as they operate, and excessive heat can lead to device failure. Heat sinks are frequently employed to transfer heat away from the device into the surrounding environment, thereby maintaining the device temperature within operational limits. A typical heat sink is constructed of copper or another metal with high thermal conductivity and has one flat surface for contacting the heat source (e.g., the top surface of the device package) and an opposing surface that includes fins or similar features to increase the surface area exposed to the environment. A thermally conductive adhesive is often used to bond the heat sink to the device package for improved heat transfer into the heat sink. Heat sinks can be further supplemented with fans that keep air flowing across the exposed surface area while the device is operating.

This conventional thermal management technology, which has been effective for many years, has its limitations. As the number and density of heat-generating elements (e.g., transistors) packed into devices has increased, the problem of heat dissipation has become a critical consideration in device and system design. It would therefore be desirable to provide improved thermal management technologies suitable for use with electronic devices.

### BRIEF SUMMARY OF THE INVENTION

Embodiments of the present invention provide nano-composite materials with enhanced thermal performance that can be used for thermal management in a wide range of applications. In electronics applications, for instance, nano-composite materials can be used to improve the thermal performance of heat sinks, device packaging, semiconductor device layers, printed circuit boards and other components. In other applications, nano-composite materials can be applied in optical and/or mechanical systems on any size scale.

According to one aspect of the present invention, a nano-composite material has a metal base material having a base thermal conductivity and nanostructures dispersed in the metal base material, the nano-composite material having a higher thermal conductivity than the base thermal conductivity. In one embodiment, the nanostructures include nanotubes (e.g., boron nitride and/or carbon nanotubes) that may be randomly oriented with respect to each other or generally aligned with each other so as to define a thermal path through at least a portion of the nano-composite material. Other nanostructures, such as fullerenes, nanorods, nanowires, nanofibers, or nanocrystals, may also be used in addition to or instead of nanotubes. The base material can be any metal, including but not limited to aluminum, copper, indium, nickel, an aluminum alloy, a copper alloy, an indium alloy, or a nickel alloy.

According to another aspect of the present invention, a nano-composite material includes a first base layer of a first base material, a second base layer of a second base material, and a film layer including a plurality of nanotubes, the film layer being disposed between and in thermal contact with each of the first and second base layers. In some embodiments, the first base material has a base thermal conductivity and the nano-composite material has a higher thermal conductivity than the base thermal conductivity. The first base material and the second base material may be of substantially the same composition, or they may be of substantially different compositions. For example, one of the first and second base materials might include copper while the other includes aluminum. In another embodiment, the nano-composite material has base layers, each made of a base material, and film layers, each comprising nanotubes. Each film layer is disposed between and in contact with a pair of the base layers.

According to yet another aspect of the present invention, an article of manufacture with enhanced thermal performance has a body having a first surface and a second surface. At least a portion of the body is formed of a nano-composite material that includes a base material and nanostructures incorporated into the base material. The nanostructures enhance thermal performance of the article, relative to a similar article made of the base material, in at least one respect. The body may be shaped for any purpose. For example, the body may be shaped as a semiconductor device, as a package for a semiconductor device, as a printed circuit board, as a heat sink, as a heat pipe, as an automobile radiator, as a plastic housing for a consumer electronic device, or as any other type of object.

According to a further aspect of the present invention, a heat transfer device for enhancing thermal transfer between an object and a region of fluid distinct from the object has a body formed of a nano-composite material that includes a base material and nanostructures incorporated into the base material. The body has first and second surfaces, with the first surface being adapted to contact the object and the second surface being adapted to contact the fluid. The second surface is characterized by macroscopic protrusions to increase a surface area that is in contact with the fluid.

According to another aspect of the present invention, a heat sink for enhancing thermal transfer between an object and a region of fluid distinct from the object has a body with a bottom contact surface adapted to contact the object and a top contact surface adapted to contact the fluid. The body is formed of a number of fin elements extending generally upward from the bottom contact surface. Each fin element has first and second side surfaces and nanotubes disposed on at least one of the first and second side surfaces of that fin element. In some embodiments, different fin elements extend upward from said bottom contact surface by different heights, and shorter fin elements may be disposed between taller fin elements. In some embodiments, a fastener is disposed at or near the bottom contact surface and adapted to fixedly hold the fin elements in position. Examples of suitable fasteners include bolts, rivets, mechanical bands, and adhesive materials. In other embodiments, the fin elements can be edge-bonded together at or near the bottom contact surface.

According to a still further aspect of the present invention, a printed circuit board is made of a nano-composite material that includes an electrically insulating base material and nanostructures incorporated into the base material. The nanostructures enhance thermal performance of the printed circuit board, relative to a printed circuit board made of the base material, in at least one respect but do not substantially enhance an electrical conductivity of the printed circuit board.

According to another aspect of the present invention, an integrated circuit device has a device layer including a heat-generating circuit component. At least a portion of the device layer is formed of a nano-composite material that includes a base material and nanostructures incorporated into the base material. The nanostructures enhance thermal performance of the integrated circuit device, relative to an integrated circuit device made of the base material, in at least one respect.

According to yet another aspect of the present invention, an integrated circuit device has a substrate layer formed of a semiconductor material, a film layer comprising nanotubes disposed on the substrate layer, and an active layer disposed on the film layer. The active layer includes at least one heat-generating circuit component. The first film layer provides a thermal path between the active layer and the substrate layer.

According to still another aspect of the present invention, a package for an integrated circuit device includes a section formed of a nano-composite material that includes a base material and nanostructures incorporated into the base material. The nanostructures enhance thermal performance of the plastic part, relative to a plastic part made of the plastic base material, in at least one respect.

According to yet a further aspect of the invention, an injection-molded plastic part includes at least one section formed of a nano-composite material that includes a base material and nanostructures incorporated into said base material. The nanostructures enhance a thermal conductivity of said base material in that section.

The following detailed description together with the accompanying drawings will provide a better understanding of the nature and advantages of the present invention.

### BRIEF DESCRIPTION OF THE DRAWINGS

FIG. 1 illustrates a nano-composite material according to one embodiment of the present invention;

FIG. 2 illustrates a nano-composite material according to another embodiment of the present invention;

FIGS. 3A-B illustrate laminate nano-composite materials according to an embodiment of the present invention;

FIGS. 4A and 4B illustrate further laminate nano-composite materials according to embodiments of the present invention;

FIG. 5 illustrates a laminate nano-composite material with non-planar layers according to an embodiment of the present invention;

FIG. 6 illustrates a laminate nano-composite material with interspersed nanotubes according to an embodiment of the present invention;

FIGS. 7A-7F illustrate heat sinks incorporating nano-composite materials according to an embodiment of the present invention;

FIG. 8 illustrates an electronic device incorporating nano-composite materials according to an embodiment of the present invention;

FIG. 9 illustrates a semiconductor device with nano-composite layers according to an embodiment of the present invention;

FIG. 10 illustrates a printed circuit board incorporating a nano-composite material according to an embodiment of the present invention;

FIG. 11 illustrates a device package incorporating a nano-composite material according to an embodiment of the present invention; and

FIGS. 12A-12C illustrate nano-composite materials according to further embodiments of the present invention.

### DETAILED DESCRIPTION OF THE INVENTION

Embodiments of the present invention provide nano-composite materials for thermal management applications and a variety of devices that can be made using these nano-composite materials, including heat sinks and other thermal transfer devices, integrated circuit device packages, semiconductor devices, printed circuit boards, and so on. The term “nano-composite material” is used herein to refer to a composite material comprising a base, or matrix, material into which are incorporated nanostructures. In some embodiments, the nanostructures are dispersed into the base material. In other embodiments, the nano-composite material has a layered structure in which some layers are made of a base material while other layers are made entirely or predominantly of nanostructures.

A wide variety of base materials (also referred to herein as “matrix materials”) can be used in embodiments of the present invention. In general, a base material for a particular application can be selected in view of desired properties such as low cost, density, electrical conductivity (or lack thereof), and so on. For instance, in some thermal management applications (e.g., heat sinks), base materials with high thermal conductivity are preferred; for other applications, other properties might be more important. The base material may have an amorphous, crystalline, polycrystalline or other structure and may itself be a composite or alloy of multiple materials. Representative base materials include various metals (e.g., copper, aluminum, indium, nickel), metal alloys, plastics and polymers (e.g., polyimide), thermoplastic and thermosetting resins, graphite, epoxies, and ceramic materials (including materials with high thermal conductivity such as aluminum nitride or boron nitride).

The term “nanostructure,” or nanoscale structure, as used herein denotes a structure with at least one dimension that is on the order of nanometers (e.g., from about 1 to 100 nm); one or more of the other dimensions may be larger and may be microscopic (from about 10 nm to a few hundred micrometers) or macroscopic (larger than a few hundred micrometers).

In embodiments of the present invention, nano-composite materials may incorporate one or more different kinds of nanostructures. For instance, in some embodiments, the nanostructures are selected for high thermal conductivity, and the proportion of nanostructures mixed or otherwise distributed into the base material matrix may vary depending on the desired thermal conductivity and other considerations. In some embodiments, the concentration of nanostructures ranges from about 1% to 75% by weight or from about 1% to 50% by volume. It is to be understood that these ranges are not limiting of the present invention; higher concentrations of nanostructures, including concentrations approaching 100%, or lower concentrations (e.g., less than 1%) might be used in some or all regions of the nano-composite material.

For thermal management applications, nanostructures having higher thermal conductivity than the base material are advantageously used to enhance the thermal conductivity of the base material so that the resulting nano-composite material has higher thermal conductivity than the base material. In preferred embodiments, the nanostructures include nanotubes having very high thermal conductivity. Nanotubes are best described as long, thin cylindrically shaped, discrete fibril structures whose diameters are on the order of nanometers. Nanotubes can exhibit lengths up to several hundred microns; thus their aspect ratios can exceed 1000. The aspect ratio can be well controlled using process conditions as is known in the art. The terms “single-wall” or “multi-wall” as used to describe nanotubes refer to nanotube structures having one or more layers of continuously ordered atoms where each layer is substantially concentric with the cylindrical axis of the structure; the nanotubes referred to herein may include single-walled and/or multi-walled nanotubes.

Nanotubes have theoretically and experimentally been shown to have high thermal conductivity along the axis of the nanotube. The thermal conductivity of carbon nanotubes, for example, has been measured at around 3000 W/m*K (theoretical calculations indicating conductivities as high as 6000 W/m*K might be achievable), as compared to conventional thermal management materials such as aluminum (247 W/m*K) or copper (398 W/m*K).

Mixing even a small concentration of nanotubes into conventional thermal management materials can significantly increase thermal conductivity. For example, a mixture of 1% carbon nanotubes (by weight) in epoxy can roughly double the base thermal conductivity of the epoxy. Calculations indicate that for copper, a nanotube concentration of about 7-10% (by weight) results in about a factor of two increase in the thermal conductivity. As another example, calculations also indicate that adding about a 10% (by weight) concentration of nanotubes to aluminum produces a nano-composite with a thermal conductivity nearly equal to that of copper, but with about one-third the weight of copper.

Nanotubes for a nano-composite material may be made of a variety of materials including carbon. In one embodiment, boron nitride (BN) nanotubes are used. The electrical properties of BN nanotubes are particularly well suited to applications where a heat transfer device is required to provide electrical isolation as well as thermal conduction because all chiralities of BN nanotubes are semiconductors with a very large bandgap that can act as electrical insulators in many applications. It will be appreciated that other materials may also be substituted.

Nanotubes can be synthesized in various ways including arc-discharge, laser ablation, or chemical vapor deposition (CVD) processes and the like. Particular synthesis techniques are not critical to the present invention. As is known in the art, many of these techniques involve depositing a catalyst material onto a substrate and growing a cluster or bundle of nanotubes where catalyst material is present. Thus, while the present description refers to nanotubes, it is to be understood that clusters or bundles of nanotubes may be used to realize aspects of the invention.

The nano-composite materials described herein enhance at least one aspect of the thermal performance of devices, structures, or other articles in which they are used. Thermal performance can be evaluated using a variety of properties. One class of thermal performance properties is inherent in the material itself, meaning that such properties are generally measured against a standard that does not depend on the quantity of material or the shape or size of the article. Examples of these properties include thermal conductivity, emissivity, absorption, or thermal transfer rates per unit surface area, and the like. Another class of thermal performance properties depends at least partly on the size and shape of the article; examples in this class include thermal dissipation rates, heat spreading characteristics (e.g., direction and/or rate of heat movement within the article), operating temperature of the article or of a device attached to the article, and so on.

Articles incorporating nano-composite materials in accordance with the present invention have improved (or enhanced) thermal performance, relative to an article of similar size, shape, and weight made entirely of the base material, as measured by any one or more of these properties. In addition, the structure or composition of a nano-composite material can be tuned in an application-specific manner to achieve desirable thermal properties (e.g., a desired thermal conductivity or desired heat spreading behavior) in articles made of the nano-composite material.

For example, in the case of heat sinks, high thermal dissipation rates are generally desirable. A heat sink made of nano-composite material with aluminum as the base material may have similar size, shape, and weight to a conventional aluminum heat sink but a significantly higher thermal dissipation rate. Depending on the particular nano-composite material used, the higher thermal dissipation may be caused by increased thermal conductivity resulting from the presence of the nanostructures, improved heat spreading characteristics, or other factors.

In some embodiments, enhanced thermal performance may also allow changes in size or weight of the article. For example, a heat sink made of nano-composite material might have the same thermal dissipation rate as a conventional heat sink but be considerably more compact (e.g., the fins might be smaller). The nano-composite heat sink would still be considered as having “enhanced thermal performance” relative to the conventional heat sink because of the superior thermal properties of the nano-composite material (e.g., thermal conductivity or emissivity) that enable the reduction in form factor.

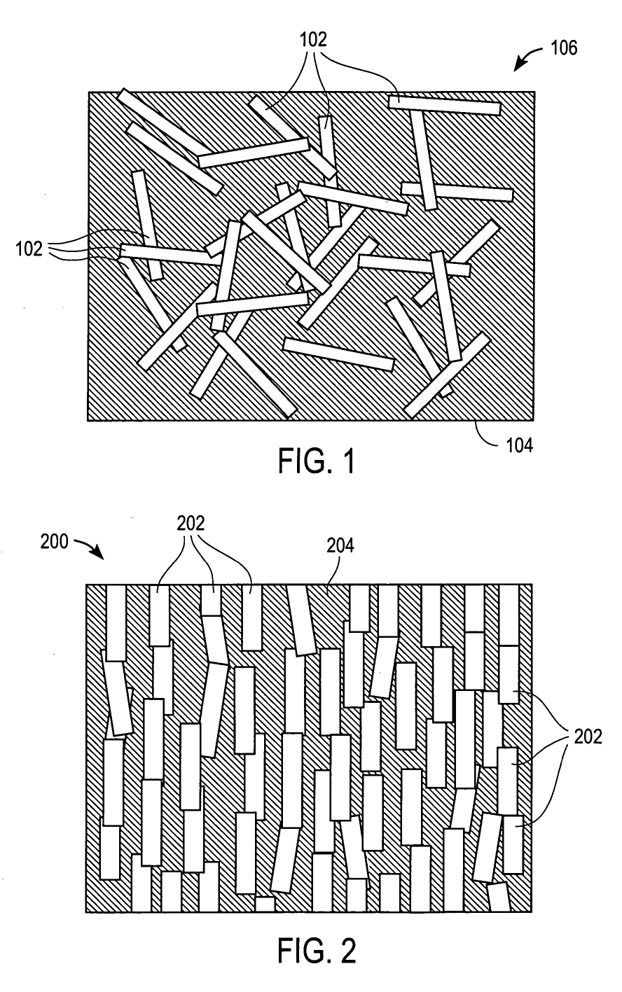

FIGS. 1-6 illustrate examples of nano-composite materials in accordance with the present invention. In FIG. 1, randomly oriented nanotubes 102 are substantially uniformly mixed into a base material 104 to form a nano-composite material 106. It should be noted that the drawings herein are not to scale. For example, nanotubes typically have a much larger aspect ratio than is depicted. In addition, some or all of the objects identified in the drawings as nanotubes could be replaced with other nanostructures, such as nanowires or nanorods.

Nano-composite material 106 can be produced, e.g., by synthesizing nanotubes first then mixing or otherwise distributing the nanotubes into the base material with a desired uniformity. In some embodiments, bundles of nanotubes may be grown and dispersed as bundles; in other embodiments, individual nanotubes are dispersed. Depending on the base material and the diameter of the nanotubes, in some instances, some or all of the nanotubes may be completely or partially filled by atoms or molecules of the base material.

In some embodiments, the nanotubes or other nanostructures are dispersed substantially uniformly throughout the base material. In other embodiments, the concentration of nanotubes or other nanostructures may vary from one region to another within the material. Where the nanostructures have higher thermal conductivity than the base material, the thermal conductivity of the nano-composite material will tend to vary with the concentration of nanotubes. Thus, thermal conductivity gradients can be established, and by selectively controlling the concentration of nanotubes in different regions of the material, thermal paths can be created, where the term “thermal path” refers to a preferred direction of heat conduction through a region.

FIG. 2 illustrates a nano-composite material 200 according to another embodiment of the present invention. In material 200, nanotubes 202 have an aligned orientation in the bulk material matrix 204; that is, the axes of the nanotubes 202 are approximately parallel. Oriented or aligned nanotubes can be synthesized in the presence of an electric field (provided, e.g., by a plasma or plates held at different potentials) as is known in the art. In one embodiment, the nanotubes are directly grown on a substrate section of the base material; after nanotube growth, spaces between the nanotubes (and optionally the interiors of the nanotubes) can be filled with additional base material. In other embodiments, the nanotubes may be grown on a separate substrate, then removed from that substrate and combined with the base material. The nanotube orientation defined during synthesis may be preserved or changed when the nanotubes are combined with the base material. Alternatively, randomly oriented nanotubes can be aligned after synthesis, e.g., by dispersing the nanotubes into the base material and applying an electric field or by using physically manipulative processes such as extrusion to form composites with aligned nanotubes.

It is to be understood that alignment of nanotubes 202 within the bulk material matrix 204 may be imperfect; such arrangements are referred to herein as being “generally aligned.” In one generally aligned configuration, a significant portion (e.g., 40% or more) of the nanotubes are aligned to each other with a mean angular deviation of 30° or less.

The thermal conductivity of boron nitride or carbon nanotubes is considerably higher along its axis than in the transverse direction; where the nanotubes are generally aligned, a thermal paths along the axial direction of the nanotubes results. For example, in material 200 heat would flow predominantly in a top-to-bottom (or bottom-to-top) direction rather than from side to side.

It will be appreciated that these nano-composite structures can be modified or varied. Various nanostructures or combinations of different nanostructures may be dispersed into a base material. Nanostructures in some regions of the material might be aligned while those in other regions are randomly oriented. Additionally, a given region might contain a mix of generally aligned and randomly oriented nanostructures.

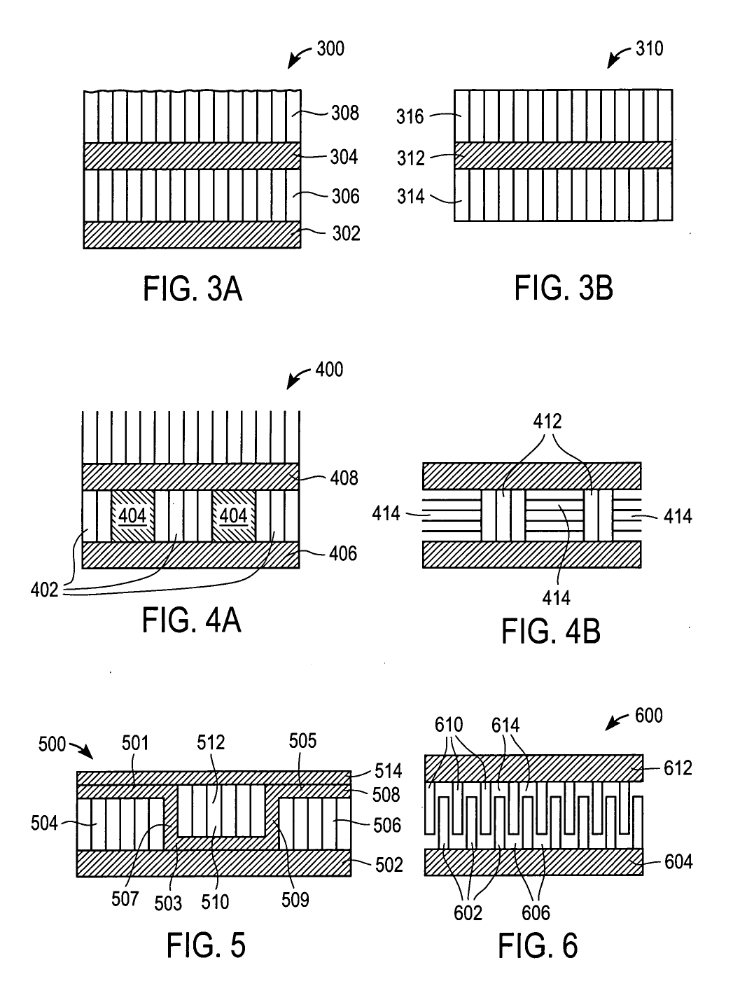

FIGS. 3-5 illustrate nano-composite materials with laminate (or layered) internal structures. FIG. 3A illustrates a laminate nano-composite material 300 in which layers 302, 304 of a matrix, or base, material are separated by film-like layers 306, 308 comprising aligned (or generally aligned) nanotubes. The matrix material may be a metal (e.g., copper), a polymer (e.g., polyimide) or any other material as mentioned above, and different layers may be made up of different base materials or different combinations of base materials. Nanotubes may be made of any suitable elements, e.g., carbon or boron nitride. In some embodiments, the interiors of some or all of the nanotubes may be wholly or partially filled with the matrix material; in other embodiments, the interiors of the nanotubes may be empty. Laminate nano-composite materials may comprise any number of layers and, in some embodiments, have a macroscopic total thickness. The top and bottom surface layers may each be made of matrix material or nanotube films as desired.

Nano-composite material 300 can be formed, e.g., by depositing a layer of a matrix material with a desired thickness on a substrate (not explicitly shown in FIG. 3A), growing nanotubes on the base material, then depositing a new layer of matrix material on top of the nanotubes and repeating the process until the desired total thickness of the material is reached. Alternatively, nanotube films can be grown on a layer of matrix material; the resulting composite may be cut into sections that are then stacked in various orientations to produce material 300.

The relative proportions of matrix material and nanotubes making up the laminate nano-composite material can be varied, for instance by varying the relative thicknesses of nanotube films 306, 308 and matrix material layers 302, 304. In one embodiment, the nanotubes are around 100 μm long, while the matrix material sheets are about 50-100 angstroms (A) (i.e., 5-10 nm) thick. In some embodiments, the matrix material is flexible or malleable, and the resulting nano-composite material may also be flexible or malleable.

In another embodiment, shown in FIG. 3B, a nano-composite material 310 has one matrix material layer 312 with a first nanotube film 314 on one side and a second nanotube film 316 on the other side. Thus, on either side of a laminate nano-composite material, either nanotubes or matrix material (or both) may be exposed.

Another way to control the relative proportions of matrix material and nanotubes is by controlling the density of the nanotubes in layers 306, 308. For instance, in material 300 nanotube layers 306, 308 are depicted as being densely packed, meaning that any gaps between neighboring nanotubes are of negligible size; for instance, neighboring nanotubes may be van der Waals bonded to each other. Dense packing, however, is not required; in other embodiments, e.g., as shown in FIG. 4A, nanotubes are grown in multiple spaced-apart clusters (or bundles) 402 on a matrix material layer 406. Such clusters can be formed by depositing a patterned catalyst for nanotube growth on the surface of matrix material layer 406 using well-known techniques, then growing nanotubes in areas where the catalyst is present.

The spaces between clusters 402 may be filled with an interstitial material 404, which may be the same matrix material used for sheets 406, 408 or a different material. For example, interstitial material 404 could be a nano-composite material. In an alternative embodiment, shown in FIG. 4B, spaces between nanotube clusters 412 may be wholly or partially filled by nanotubes 414 with a different (in this example, horizontal) orientation. In still another embodiment, spaces between nanotube clusters 412 might be filled with other interstitial materials, including air or other viscous fluids, or a deposited film (of any material) that has good conformal behavior.

In another embodiment, a laminate structure with non-planar layers, such as material 500 shown in FIG. 5, may be formed. On a layer 502 of matrix material, spaced-apart bundles of nanotubes 504, 506 are grown, deposited, or otherwise placed. A second layer 508 of matrix material is deposited over the top of nanotubes 504, 506. It should be noted that layer 508 is contoured rather than planar and has a “valley” or gap region 510. Additional nanotubes 512 can be grown to fill in valley region 510 and another (in this case, substantially planar) layer of matrix material 514 deposited over the top. In some embodiments, different portions of a contoured layer such as layer 508 may have different thicknesses; for instance, horizontal sections 501, 503, 505 and vertical sections 507, 509 might all have different thicknesses.

Additional contoured or planar layers may be formed as desired. It will be appreciated that any contour shape may be formed, and that gaps may be filled with matrix material, nanotubes (in any orientation) or other materials including nano-composite materials. In general, a laminate nano-composite material may have contoured or planar layers in any combination.

Where the nanotubes have higher thermal conductivity than the matrix material(s), use of laminate structures can provide enhanced control over the net thermal conductivity of the material as well as the possibility of deliberately creating thermal conductivity gradients within the material; such gradients can be used to define thermal paths of arbitrary shape.

FIG. 6 illustrates yet another embodiment of a laminate nano-composite material 600, in which the nanotube film has two “sublayers.” Nanotubes 602, which form a first sublayer, are grown, deposited, affixed, or otherwise placed on a matrix material layer 604. Nanotubes 602, which may be realized as bundles or clusters of nanotubes as described above, are advantageously arranged with spaces 606 therebetween. Similarly, nanotubes 610, which form a second sublayer, are grown, deposited, affixed, or otherwise placed on a matrix material layer 612. As with nanotubes 602, spaces 614 can be provided between adjacent bundles or clusters of nanotubes 610. The two sublayers are then pushed together to create an interspersed arrangement of nanotubes 602 and 610 as shown. In some embodiments, the density of nanotubes 602 and 610 is such that the resulting film layer forms a substantially continuous film (e.g., with van der Waals bonds between adjacent nanotubes). In other embodiments, any spaces between nanotubes 602 and nanotubes 610 may be filled with an interstitial material such as air, other viscous fluid media, or solid materials.

It will be appreciated that the laminate nano-composite materials described herein are illustrative and that variations and modifications are possible. For example, while the nanotube films are described herein as containing generally aligned nanotubes, other nanotube films with randomly oriented nanotubes might also be used. In addition, nanotubes in a nanotube film could be aligned at an oblique angle to the surface of a base layer; the design choices are not limited to the perpendicular or parallel alignments shown in FIGS. 3-6.

In some embodiments of nano-composite materials in which the nanostructures include nanotubes, the ends of the nanotubes may be specially treated to improve heat transfer between the nanotubes and the matrix material. For example, after nanotubes are grown, they may be treated, e.g., by exposing one or both ends of the nanotubes to an oxygen plasma or energetic oxygen that etches away any closed ends, opening the nanotubes. After this treatment, a film of thermally conductive material such as copper, aluminum or indium is deposited on the nanotube tips. In the case of a laminate nano-composite material, this film may be the next layer of matrix material (or a part of that layer), or the matrix material layer can be applied over the film. Further details regarding treatment of nanotube ends can be found in above-referenced application Ser. No. ______ (Attorney Docket No. 022353-000410US).

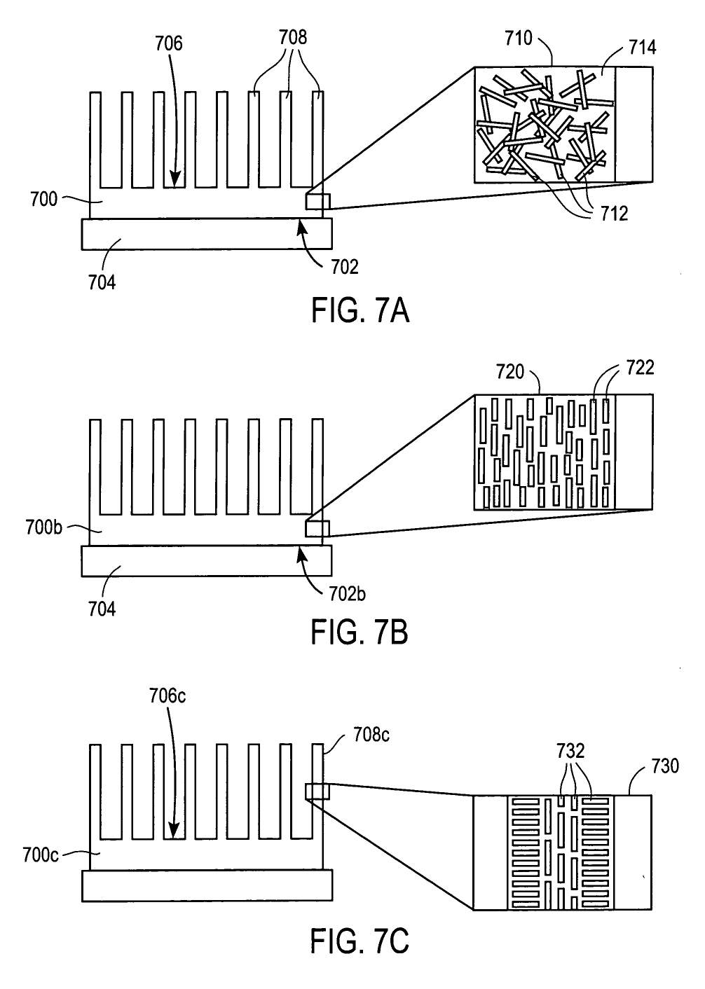

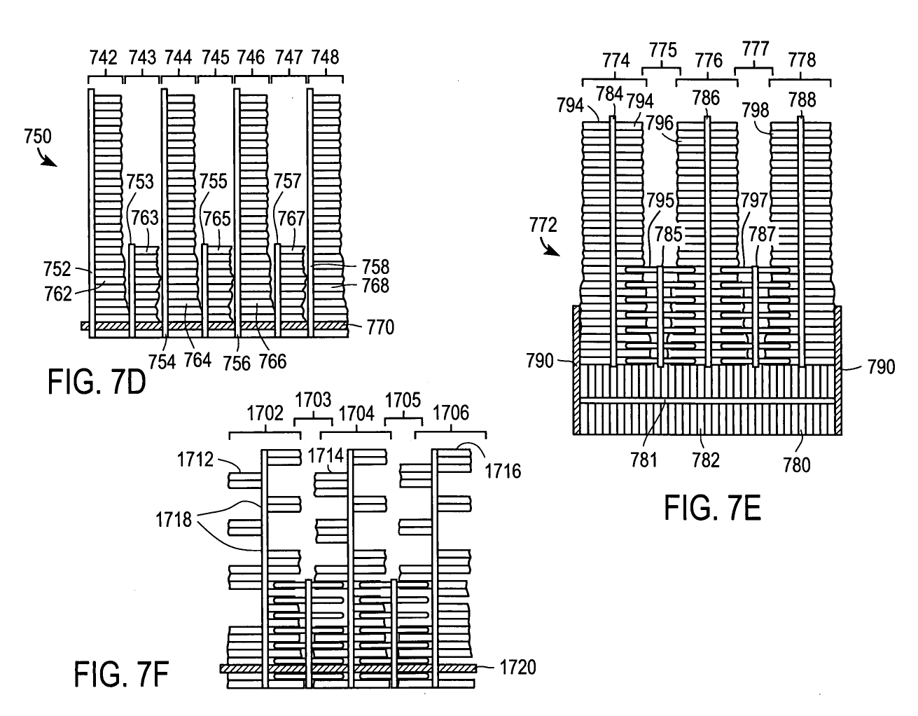

Any of the nano-composite materials described above may be used to form a heat sink with enhanced thermal conductivity, e.g., as illustrated in FIGS. 7A-7C. Heat sink 700, which macroscopically is similar to conventional heat sinks, has a device-contacting surface 702 that is adapted to be placed in contact with a heat-producing device 704. Surface 702 may be adapted for contact in a variety of ways. In some embodiments, surface 702 may be shaped and/or sized so as to maximize the contact area between heat sink 700 and device 704, for example, by providing a curvature for heat-sink surface 702 that conforms to a curvature of a contact surface 703 of device 704 (if device surface 703 is planar, heat-sink surface 702 would also be planar) and/or by making heat sink surface 702 at least as large as the device surface 703. Additionally or alternatively, surface 702 may be made of a material that can be molded or flexed to increase the contact area, or surface 702 may be coated with a substance that improves thermal contact.

Heat sink 700 has another surface 706 that is adapted for exposure to an environment, also referred to herein as a “region of fluid,” such as air at approximately room temperature and standard pressure. Surface 706 may be adapted in a variety of ways; preferably, surface 706 presents a relatively large surface area to the environment so as to promote convective heat transfer between heat sink 700 and the environment. In the embodiment of FIG. 7A, surface 706 includes macroscopic protrusions 708 that increase the surface area exposed to the environment. Protrusions 708 are shaped as fins having a generally rectangular cross section and pin-like, post-like or plate-like shapes; other shapes could also be used.

Although the macroscopic appearance of heat sink 700 is generally similar to that of conventional heat sinks, its microscopic structure is different because heat sink 700 is composed of a nano-composite material. In one embodiment, as shown by inset 710, the nano-composite material includes randomly oriented nanotubes 712 embedded in a matrix material 714.

In other embodiments, nano-composite materials incorporating aligned nanotubes can be used to create thermal pathways that promote heat transfer in desired directions. To the extent that the thermal conductivity of the nanotube is greater in the longitudinal direction than the transverse direction (as is the case for both carbon and boron nitride nanotubes), heat will be preferentially transferred along the length of the nanottibe rather than transversely from one nanotube to a neighbor. In a heat sink, such paths can be used to direct heat away from the heat-generating device and toward the opposite surface. For example, inset 720 in FIG. 7B illustrates an embodiment of a heat sink 700b in which, near device-contacting surface 702b, the nanotubes 722 are generally aligned so that their axes are approximately normal to surface 702b. This arrangement can enhance the ability of heat sink 700 to conduct heat away from heat-producing device 704.

In FIG. 7C, inset 730 illustrates an arrangement of nanotubes that may advantageously be provided to distribute heat across the exposed surface 706c of a heat sink 700c. As shown in inset 730, nanotubes 732 are aligned so that heat is directed from a bulk portion of heat sink 700c toward the side and top surfaces of the fins 708c. In some embodiments, laminate structures such as those described above may be used to create the arrangement shown in inset 730. In an alternative embodiment, nanotubes may be grown with bent shapes (e.g., by varying the electric field applied during nanotube growth) and arranged in the matrix material to provide the desired paths.

FIG. 7D illustrates yet another heat sink configuration according to an embodiment of the present invention. Heat sink 740 is made of a nano-composite material similar to that shown in FIG. 3. Each layer 742-748 includes a matrix material layer 752-758 that is coated on one side with a film 762-768 of generally aligned nanotubes, and the layers are stacked as shown. The matrix material layers 752-758 are advantageously made of a thermally conductive material such as copper, aluminum, indium or the like. In some embodiments, different matrix materials are used for different ones of layers 752-758; for example, aluminum matrix material in layers 752, 754, 756, 758 might alternate with copper matrix material in layers 753, 755, 757. Other combinations are also possible.

In one embodiment, layers 742-748 are made thick enough to resist transverse deformation during handling or operation; they may be macroscopically thick. Layers 742-748 can be formed by fabricating a matrix material sheet having a large area, depositing a nanotube film over substantially the entire surface of the matrix material sheet, then stamping or otherwise separating the nanotube-coated sheet into the desired layer shapes. Other fabrication processes may also be used.

Layers 742-748 have their bottom edges are aligned and are secured together by a connector 770 at or near the bottom edge. Connector 770 may be implemented in a variety of ways. For example, one or more holes may be bored in through layers 742-748, and a rivet or bolt or other similar fastener may be inserted through each hole. Alternatively, the layers may be bonded to each other at or near their bottom edges using suitable adhesives or bonding agents or a mechanical band around the edge that holds the layers 742-748 in the desired relative positions.

Heat sink 750 has a bottom surface 762 adapted for conductive heat transfer and a top surface 764 adapted for convective heat transfer. More specifically, in this embodiment, bottom surface 762 is advantageously made macroscopically smooth to maximize a thermal contact area between heat sink 750 and a heat-producing device (not shown in FIG. 7D). Suitable smoothness can be achieved by conventional techniques, including high-precision alignment of the layers 742-748 during device assembly, stripping excess material from bottom surface 762 after device assembly (e.g., by cutting, lapping, polishing or similar processes), or coating bottom surface 762 with nanotubes or thermal grease.

In this embodiment, top surface 764 provides increased surface area to promote convective heat transfer between heat sink 750 and an environment. Specifically, layers 742-748 include layers of varying height; taller layers 742, 744, 746, 748 alternate with shorter layers 743, 745, 747. Shorter layers 743, 745, 745 are advantageously arranged to provide sufficient spacing between taller layers 742, 744, 746, 748 so that a circulating fluid in the environment (e.g., air) can flow between taller layers 742, 744, 746, 748. The nanotubes in films 752, 754, 756, 758 can also be arranged such that the circulating fluid can flow between them, thereby further increasing the surface area exposed to the environment. Arrangement of nanotubes on surfaces to increase surface area is described further in above-referenced co-pending application Ser. No. ______ (Attorney Docket No. 022353-000210US).

FIGS. 7E and 7F illustrate some of the possible variations on heat sink 750. In FIG. 7E, a heat sink 772 has layers 774-778, each made of a base material 784-788 that has nanotube films 794-798 deposited on both sides. Adjacent portions of films on different base layers (e.g., films 794 and 795) can be interlaced, similarly to the arrangement shown in FIG. 6 and described above. Heat sink 772 also has a bottom layer 780 in a plane normal to layers 774-778; layer 780 has a base material 781 that is coated on both sides with a nanotube film 782. In this example, edge bonding material 790 holds the layers 774-778 and 780 in place; conventional edge bonding techniques may be used. Other fasteners and fastening techniques may be used in place of or in addition to edge bonding material 790.

In FIG. 7F, a heat sink 1700 has layers 1702-1706, which are generally similar to layers 774-778 in heat sink 772 of FIG. 7E, except that the nanotube films 1712, 1714, 1716 are discontinuous with gaps 1718 (which may be, e.g., on the order of microns) between adjacent bundles of nanotubes. Layers 1702-1706 are held together by a connector 1720, which may be generally similar to connector 770 in FIG. 7D.

It will be appreciated that the heat sinks in FIGS. 7D-7F are illustrative and that variations and modifications are possible. For example, any number of layers having different shapes may be used, different layers may be made of different materials, and some layers might not have nanotube film coatings. In addition, the layers might or might not be planar, or they might extend away from the bottom surface at an oblique angle. To further space apart taller layers, multiple shorter layers can be placed between two taller layers. In addition, multiple taller layers may be placed adjacent to each other, e.g., to increase mechanical strength of the device.

In still other embodiments, heat sinks may be formed using nano-composite materials that incorporate other nanostructures instead of or in addition to the nanotubes shown in FIGS. 7A-7F. In some embodiments, heat sinks are formed by creating a quantity of a nano-composite material, e.g., as described above, then forming the material into the desired shape using generally conventional processes such as molding, extrusion or stamping.

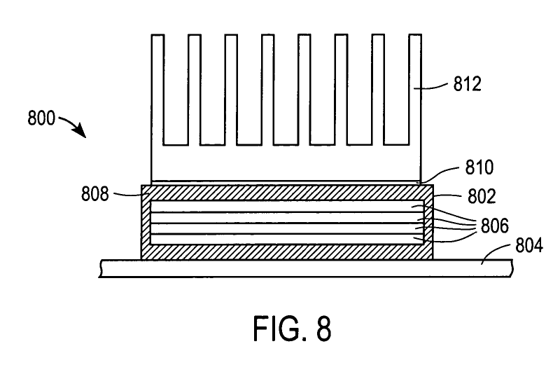

In addition to heat sinks, the present invention may be embodied in a variety of other thermal transfer devices. For example, in the electronics field, heat spreaders, device packaging materials, adhesives for bonding heat sinks to device packaging, or internal layers within the device may incorporate suitable nano-composite materials. FIG. 8 illustrates an electronics product 800 including an integrated circuit device (chip) 802 mounted on a printed circuit board (PCB) 804. Chip 802 includes one or more internal device layers 806 contained within hermetic packaging 808. An adhesive layer 810 bonds hermetic packaging 808 to a heat sink 812. Nano-composite materials as described above may be incorporated into any or all of PCB 804, internal device layers 806, hermetic packaging 808, adhesive layer 810 and heat sink 812; alternatively, some of these elements may use conventional materials.

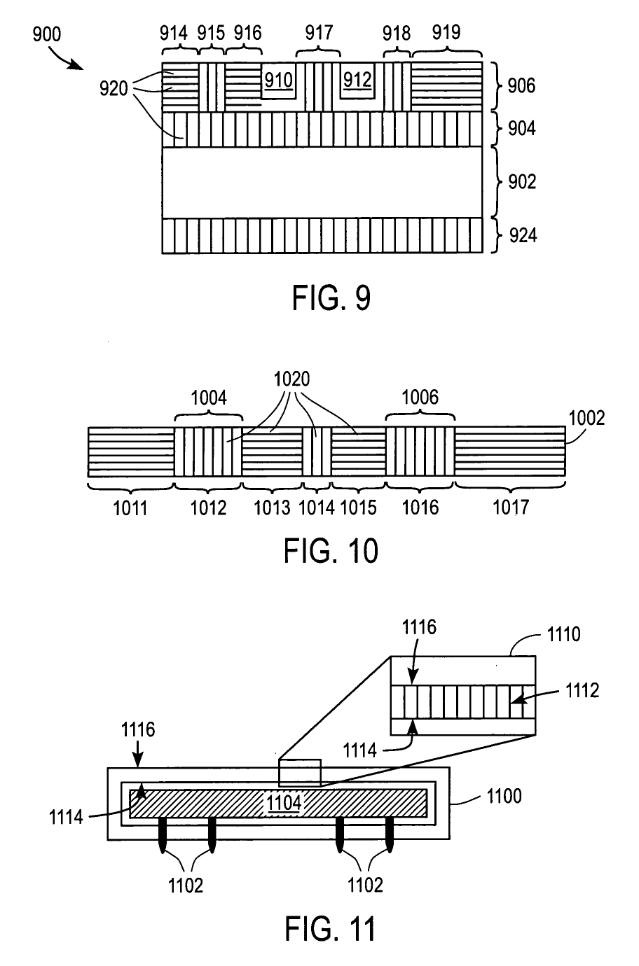

In one embodiment, oriented nanotubes are disposed within device layers 806 of chip 802. For example, FIG. 9 illustrates a semiconductor device 900 incorporating a nanotube-containing nano-composite material. Device substrate 902 may be of a conventional semiconductor material (e.g., silicon, germanium, gallium arsenide). A layer 904 of nano-composite material with vertically oriented nanotubes is grown or deposited on the top surface of device substrate 902. An active layer 906 is formed over nano-composite layer 904. Active layer 906 includes semiconductor circuit elements 910, 912 (which may be, e.g., transistors, capacitors or diodes fabricated using conventional techniques) as well as sections 914-919 that include nano-composite material with oriented nanotubes 920. In some embodiments, a layer 924 of nano-composite material may also be grown or deposited on the bottom surface of device substrate 902 to facilitate heat dissipation from below.

In sections 914-919, the nanotubes 920 are advantageously arranged to define desired heat conduction paths around circuit elements 910, 912. For example, section 916 has nanotubes oriented horizontally that can direct heat away from circuit element 910 toward section 915. In section 915, the nanotubes 920 are oriented vertically to direct heat toward a top side 922 and/or a bottom side 924 of active layer 906; the temperature gradient between top side 922 and bottom side 924 will determine the actual direction of heat flow. As another example, in section 917, the nanotubes 920 are oriented vertically so that heat entering section 917 is directed past, rather than into, circuit elements 910, 912. In another embodiment (not explicitly shown in FIG. 9), nanotubes may be oriented with their axes extending radially outward from a circuit element.

Nano-composite layer 904, disposed between active layer 906 and device substrate 902, also serves to direct heat along a desired path. For example, active layer 906 in one embodiment includes heat-producing circuit elements 910, 912 while device substrate 902 has no heat-producing elements. The vertical orientation of nanotubes 920 would tend to promote heat transfer away from active layer 906 and into device substrate 902 as long as a thermal gradient exists between the layers. This can help to reduce mechanical stresses on device 900 that may be caused by thermal gradients between layers.

Nanotubes 920 in sections 914-919 as well as layer 904 may be made of any suitable material. In some embodiments, boron nitride nanotubes are advantageously used, particularly for sections 914-919; because all chiralities of BN nanotubes are semiconducting with large bandgaps, use of BN nanotubes will not adversely affect the electrical properties of device 900. It is to be understood that nanotubes of different composition may be used in different places within device 900.

Referring again to FIG. 8, in other embodiments, nano-composite materials are incorporated into PCB 804. Conventional PCBs are made of a bulk electrically insulating material (e.g., G10 glass/epoxy composition, FR4) on or within which copper or other conductive traces can be formed. The electrical insulators typically used in PCBs tend to be poor thermal conductors. Incorporation of electrically semiconducting or insulating nano-composite materials (such as BN nanotubes) into PCBs in accordance with an embodiment of the present invention can improve the thermal conductivity of the PCB while preserving the desired electrical properties. In regions where electrical isolation is not critical, carbon nanotubes or other electrically conductive nanostructures might be used.

More specifically, FIG. 10 illustrates a PCB 1002 formed from nano-composite materials. Heat-producing devices 1004, 1006, which may be, e.g., integrated circuit devices, discrete circuit elements, power supply circuits or the like, can be mounted to PCB 1002 as shown after fabrication of PCB 1002. PCB 1002 includes sections 1011-1017 formed of nano-composite material with generally aligned nanotubes 1020 as shown. The base material is advantageously chosen for its electrically insulating properties and may be a conventional PCB material such as G10, FR4 or ceramics.

The nanotubes 1020 in sections 1011-1017 are advantageously oriented to provide desired thermal paths within and through PCB 1002. In sections 1012 and 1016 (near where devices 1004 and 1006 would be mounted), the nanotubes are oriented vertically to promote heat transfer through PCB 1002 away from devices 1004, 1006. The adjacent sections 1011, 1013, 1015, 1017 have nanotubes that are horizontally oriented to disperse heat laterally across PCB 1002. Section 1014 has vertically oriented nanotubes to direct heat toward the top and/or bottom surfaces of PCB 1002.

As in device 900, the nanotubes in PCB 1002 may advantageously be BN nanotubes. Since BN nanotubes are semiconducting, BN nanotubes may be disposed in the PCB material without concern for any conductive traces that may be placed on or in PCB 1002. Carbon nanotubes may also be used if they are electrically isolated from any conductive traces or if the carbon nanotubes include only semiconducting chiralities.

In other embodiments, other nanostructures that enhance thermal conductivity without creating well-defined thermal paths can be dispersed into the bulk material of a PCB. Examples of such nanostructures include randomly-oriented nanotubes (e.g., as shown in FIG. 1), “diamond dust” (i.e., diamond crystals with nanoscale dimensions), or other nanocrystals with high thermal conductivity.

Referring again to FIG. 8, in still other embodiments, nano-composite materials may be incorporated into device package 808. FIG. 11 illustrates a device package 1100 that has contact pins 1102 for coupling an integrated circuit 1104 housed inside package 1100 to other components. As shown in inset 1110, at least some sections of package 1100 are formed of a nano-composite material with oriented nanotubes 1112 that extend between an inner surface 1114 and an outer surface 1116 of package 1110. Nanotubes 1112 provide an enhanced thermal path from the inside of the package to the outside of the package, thereby facilitating heat transfer away from integrated circuit device 1104.

It will be appreciated that the particular arrangements or orientations of nanotubes described herein are illustrative and that a wide variety of thermal paths may be created by using nano-composite material with a suitable arrangement of nanotubes dispersed therein. The paths can be modified to provide desired thermal behavior. Nano-composite materials of the type described above with reference FIG. 2, a layered composition as described above with reference to FIGS. 3-5, or other forms of nano-composite materials with aligned nanotubes may be used. Alternatively, a nano-composite material that does not define thermal paths, such as a nano-composite material where the nanostructures are randomly-oriented nanotubes or nanocrystals, may also be used in any of the structures identified in FIG. 8.

In other embodiments, nano-composite materials may be used in the manufacture of portions of consumer products that are not traditionally associated with thermal management. For example, laptop and desktop computers, phones, personal digital assistants (PDA), and other consumer electronics products typically have injection-molded plastic cases or housings that provide good electrical insulation. In accordance with the present invention, the thermal conductivity of such plastics (e.g., polyimide and others) can be enhanced by incorporating therein nanostructures having higher thermal conductivity than the plastic. For example, boron nitride nanotubes, which are semiconducting with a large bandgap, may be used to produce a material of the type illustrated in FIG. 1 or FIG. 2. The proportion of nanostructures can be optimized for a particular application based on considerations related to the desired thermal and electrical properties of the plastic. Nano-composite plastics can then be formed into appropriate shapes for the product in question, using injection molding or other conventional techniques. The presence of the nano-composite plastic can improve the overall ability of the product (e.g., laptop, phone or PDA) to dissipate heat generated by its internal components.

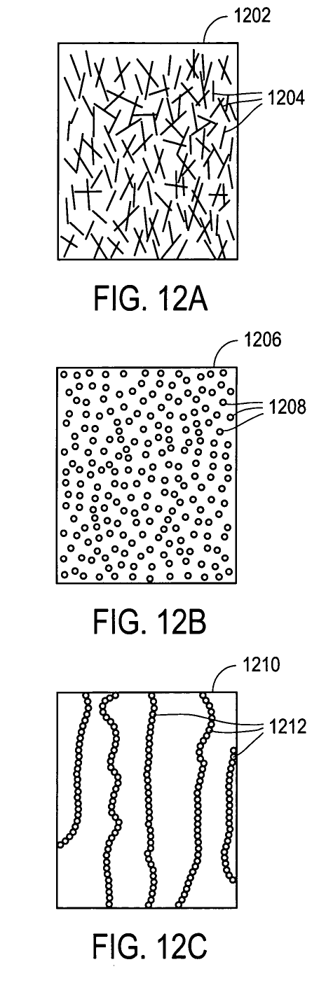

While the invention has been described with respect to specific embodiments, one skilled in the art will recognize that numerous modifications are possible. For instance, in embodiments shown herein, nanotubes (e.g., carbon or boron nitride nanotubes) are used as the nanostructures in the nano-composite material. In other embodiments, other types of nanostructures may be used, including nanorods, nanofibers, nanocrystals, fullerenes, and other nanoscale structures such as diamond dust made from crystalline or CVD diamond flecks, chains of nanocrystals or fullerenes. Examples are illustrated in FIGS. 12A-12C, with FIG. 12A showing a nano-composite material 1202 including nanorods 1204, FIG. 12B showing a nano-composite material 1206 including nanocrystals 1208, and FIG. 12C showing a nano-composite material 1210 including chains of nanocrystals 1212. In still other embodiments, a combination of different nanostructures may be used, e.g., a combination of boron nitride and carbon nanotubes or a combination of nanotubes with nanocrystals. Thermal transfer devices incorporating nano-composite materials may be realized in a variety of sizes and shapes for various applications.

The present invention may also be used for thermal transfer or thermal management elements in electrical, optical or mechanical systems of any size scale. For example, nano-composite materials may be incorporated into heat pipes for a wide variety of applications. Heat pipes are well known devices for transporting heat from one location to another. A heat pipe includes a container (typically of a tubular shape) filled with a suitable fluid. An inner surface of the container is coated with a porous material that provides capillary action. When the pipe is exposed to a thermal gradient in a suitable temperature range, the fluid at the hotter end of the pipe evaporates; the resulting gas moves to the cooler end of the pipe where it condenses and is returned to the hotter end by the capillary action of the porous material. A nano-composite material as described herein could be used to coat the inside of a capillary or other micro-channel for improved thermal transfer performance.

Suitable nano-composite materials may also be incorporated into thermal transfer devices for automotive applications, e.g., in engine blocks or radiators or other components, as well as other mechanical systems (e.g., refrigeration, air conditioning or heating units).

Thus, although the invention has been described with respect to specific embodiments, it will be appreciated that the invention is intended to cover all modifications and equivalents within the scope of the following claims.

1. A nano-composite material comprising:
a metal base material having a base thermal conductivity; and
a plurality of nanostructures dispersed in said metal base material,
wherein said nano-composite material has a higher thermal conductivity than the base thermal conductivity.

2. The nano-composite material of claim 1 wherein said nanostructures include nanotubes.

3. The nano-composite material of claim 2 wherein said nanotubes are randomly oriented with respect to each other.

4. The nano-composite material of claim 2 wherein said nanotubes are generally aligned with each other so as to define a thermal path through at least a portion of the nano-composite material.

5. The nano-composite material of claim 2 wherein said nanotubes include boron nitride nanotubes.

6. The nano-composite material of claim 2 wherein said nanotubes include carbon nanotubes.

7. The nano-composite material of claim 1 wherein said metal base material includes at least one metal selected from a group consisting of aluminum, copper, indium, nickel, aluminum alloys, copper alloys, indium alloys, and nickel alloys.

8. The nano-composite material of claim 1 wherein the concentration of said nanostructures is between about 1% and about 25% by weight.

9. The nano-composite material of claim 1 wherein the concentration of said nanostructures is between about 1% and about 25% by volume.

10. The nano-composite material of claim 1 wherein the thermal conductivity of said nano-composite material is higher than the base thermal conductivity by a factor of at least about two.

11. The nano-composite material of claim 1 wherein said nanostructures are substantially uniformly dispersed in said metal base material.

12. The nano-composite material of claim 1 wherein said nanostructures include one or more nanostructures selected from the group consisting of nanotubes, fullerenes, nanorods, nanofibers, and nanocrystals.

13. A nano-composite material comprising:
a first base layer of a first base material;
a second base layer of a second base material; and
a film layer including a plurality of nanotubes, said film layer being disposed between and in thermal contact with each of said first and second base layers.

14. The nano-composite material of claim 13 wherein said first base material has a base thermal conductivity and said nano-composite material has a higher thermal conductivity than the base thermal conductivity.

15. The nano-composite material of claim 13 wherein said first base material and said second base material are of substantially the same composition.

16. The nano-composite material of claim 13 wherein said first base material and said second base material are of substantially different compositions.

17. The nano-composite material of claim 16 wherein one of said first and second base materials includes copper and wherein the other of said first and second base materials includes aluminum.

18. The nano-composite material of claim 13 wherein said nanotubes in said film layer are arranged with spaces between at least some of said nanotubes and others of said nanotubes.

19. The nano-composite material of claim 18 wherein the film layer further comprises an interstitial material substantially filling said spaces between said nanotubes.

20. The nano-composite material of claim 18 wherein said interstitial material is made of the base material.

21. The nano-composite material of claim 18 wherein said interstitial material is a viscous fluid material.

22. The nano-composite material of claim 18 wherein said interstitial material is a deposited film that substantially conforms to said spaces.

23. The nano-composite material of claim 13 wherein said nanotubes in said film layer are densely packed.

24. The nano-composite material of claim 13 wherein said film layer further includes a gap region characterized by an absence of nanotubes and wherein said second layer extends into said gap region.

25. The nano-composite material of claim 13 wherein said nanotubes are generally aligned with each other.

26. The nano-composite material of claim 25 wherein said nanotubes are further generally aligned at substantially right angles to the first layer.

27. The nano-composite material of claim 13 wherein said film layer further includes a first region comprising nanotubes that are generally aligned to a first axis and a second region comprising nanotubes that are generally aligned to a second axis, wherein the first axis and the second axis define different directions.

28. The nano-composite material of claim 27 wherein the first axis is substantially perpendicular to the second axis.

29. The nano-composite material of claim 27 wherein the first layer is substantially planar, the first axis is substantially perpendicular to the first layer and the second axis is substantially parallel to the first layer.

30. The nano-composite material of claim 13 wherein said first layer and said second layer are substantially planar.

31. The nano-composite material of claim 13 wherein said base material comprises a metal.

32. The nano-composite material of claim 31 wherein said metal is selected from a group consisting of aluminum, copper, indium, aluminum alloys, copper alloys, and indium alloys.

33. The nano-composite material of claim 13 wherein said base material comprises a semiconductor material.

34. The nano-composite material of claim 33 wherein said semiconductor material is selected from a group consisting of silicon, germanium, and gallium arsenide.

35. The nano-composite material of claim 13 wherein said base material comprises a polymer.

36. The nano-composite material of claim 13 wherein said film layer includes interspersed nanotubes of a first film sublayer and a second film sublayer, said first film sublayer being attached to said first base layer; and said second film sublayer being attached to said second base layer.

37. A nano-composite material comprising:
a first plurality of base layers, each base layer made of a base material; and
a second plurality of film layers, each film layer comprising nanotubes, each of said film layers being disposed between and in contact with a pair of layers in said plurality of base layers.

38. The nano-composite material of claim 37 wherein said nano-composite material has a higher thermal conductivity than any of the base layers.

39. The nano-composite material of claim 37 wherein each of the base layers is made of the same base material.

40. The nano-composite material of claim 37 wherein at least one of said film layers includes interspersed nanotubes of a first film sublayer and a second film sublayer, said first film sublayer being attached to a first one of said base layers; and said second film sublayer being attached to a second one of said base layers.

41. An article of manufacture with enhanced thermal performance, the article comprising:
a body having a first surface and a second surface,
wherein at least a portion of said body is formed of a nano-composite material that includes a base material and nanostructures incorporated into said base material, and
wherein said nanostructures enhance thermal performance of the article, relative to a similar article made of the base material, in at least one respect.

42. The article of claim 41 wherein said enhanced thermal performance in at least one respect includes a higher thermal transfer efficiency through said portion of said body.

43. The article of claim 41 wherein said enhanced thermal performance in at least one respect includes a higher thermal conductivity.

44. The article of claim 41 wherein said first surface is adapted for convective heat transfer between the body portion and a region of fluid.

45. The article of claim 41 wherein said first surface is adapted for conductive heat transfer between the body portion and another object.

46. The article of claim 41 wherein said nanostructures have a higher thermal conductivity than said base material.

47. The article of claim 41 wherein said nanostructures include nanotubes.

48. The article of claim 47 wherein said nanotubes are randomly oriented.

49. The article of claim 47 wherein said nanotubes are generally aligned with each other.

50. The article of claim 47 wherein said nano-composite material includes a nanotube film layer disposed between two layers of said base material.

51. The article of claim 50 wherein the nanotubes in said nanotube film layer are generally aligned with each other.

52. The article of claim 51 wherein axes of the nanotubes in said nanotube film layer are substantially normal to a surface of one of said two layers of said base material.

53. The article of claim 47 wherein said nanotubes include at least one of carbon nanotubes or boron nitride nanotubes.

54. The article of claim 41 wherein said nanostructures include one or more nanostructures selected from the group consisting of nanotubes, fullerenes, nanorods, nanofibers, and nanocrystals.

55. The article of claim 41 wherein said base material includes one or more materials selected from the group consisting of copper, aluminum, steel, titanium, and polyimide.

56. The article of claim 41 wherein said body is shaped as a package for a semiconductor device.

57. The article of claim 41 wherein said body is shaped as a semiconductor device.

58. The article of claim 41 wherein said body is shaped as a printed circuit board

59. The article of claim 41 wherein said body is shaped as a heat sink.

60. The article of claim 41 wherein said body is shaped as a heat pipe.

61. The article of claim 41 wherein said body is shaped as an automobile radiator.

62. The article of claim 41 wherein said body is shaped as a plastic housing for a consumer electronic device.

63. A heat transfer device for enhancing thermal transfer between an object and a region of fluid distinct from the object, the heat transfer device comprising:
a body formed of a nano-composite material that includes a base material and nanostructures incorporated into said base material, said body having first and second surfaces,
said first surface being adapted to contact the object; and
said second surface being adapted to contact the fluid, said second surface being characterized by macroscopic protrusions to increase a surface area that is in contact with the fluid.

64. The heat transfer device of claim 63 wherein said protrusions on said second surface are in the form of fins having generally rectangular cross-sectional profiles.

65. The heat transfer device of claim 63 wherein said nanostructures have a higher thermal conductivity than said base material.

66. The heat transfer device of claim 63 wherein said nanostructures include nanotubes.

67. The heat transfer device of claim 66 wherein said nanotubes are randomly oriented.

68. The heat transfer device of claim 66 wherein said nanotubes are generally aligned with each other.

69. The heat transfer device of claim 66 wherein said nano-composite material includes a nanotube film layer disposed between two layers of said base material.

70. The heat transfer device of claim 69 wherein the nanotubes in said nanotube film layer are generally aligned with each other.

71. The heat transfer device of claim 70 wherein axes of the nanotubes in said nanotube film layer are substantially normal to a surface of one of said two layers of said base material.

72. The heat transfer device of claim 66 wherein said nano-composite material includes a plurality of layers of said base material, each of said layers having a nanotube film layer disposed on at least one side thereof.

73. The heat transfer device of claim 66 wherein said nanotubes include at least one of carbon nanotubes or boron nitride nanotubes.

74. The heat transfer device of claim 63 wherein said nanostructures include one or more nanostructures selected from the group consisting of nanotubes, fullerenes, nanorods, nanofibers, and nanocrystals.

75. The heat transfer device of claim 63 wherein said base material includes a metal.

76. The heat transfer device of claim 75 wherein said metal is selected from the group consisting of aluminum, copper, indium, aluminum alloys, copper alloys, and indium alloys.

77. A heat sink for enhancing thermal transfer between an object and a region of fluid distinct from the object, the heat sink comprising:
a body having a bottom contact surface adapted to contact the object and a top contact surface adapted to contact the fluid,
wherein said body is formed of a plurality of fin elements extending generally upward from said bottom contact surface, each fin element having first and second side surfaces,
each fin element further having a plurality of nanotubes disposed on at least one of the first and second side surfaces of that fin element.

78. The heat sink of claim 77 wherein different ones of said fin elements extend upward from said bottom contact surface by different heights.

79. The heat sink of claim 78 wherein shorter ones of said fin elements are disposed between taller ones of said fin elements.

80. The heat sink of claim 77 wherein said first and second side surfaces of each of said fin elements extend upward from said bottom contact surface in a direction substantially normal to said bottom contact surface.

81. The heat sink of claim 77 wherein said first and second side surfaces of each of said fin elements are substantially planar.

82. The heat sink of claim 77 wherein said body further includes:
a bottom layer disposed below said fin elements and oriented substantially parallel to said bottom contact surface; and
a plurality of nanotubes disposed on at least one surface of said bottom layer.

83. The heat sink of claim 77 wherein at least one of said fin elements has nanotubes disposed on both of the first and second side surfaces of that fin element.

84. The heat sink of claim 77 further comprising a fastener disposed at or near said bottom contact surface and adapted to fixedly hold said fin elements in position.

85. The heat sink of claim 84 wherein said fastener is a bolt or a rivet.

86. The heat sink of claim 84 wherein said fastener is a mechanical band.

87. The heat sink of claim 84 wherein said fastener includes an adhesive material.

88. The heat sink of claim 84 wherein said fin elements are edge-bonded together at or near said bottom contact surface.

89. The heat sink of claim 77 wherein said nanotubes include carbon nanotubes and/or boron nitride nanotubes.

90. The heat sink of claim 77 wherein said nanotubes form a substantially continuous film on the base layers.

91. The heat sink of claim 77 wherein said nanotubes are arranged in spaced-apart bundles, each bundle including one or more nanotubes.

92. The heat sink of claim 77 wherein said nanotubes on one of said fin elements are generally aligned along a common axis.

93. The heat sink of claim 92 wherein said common axis is substantially normal to a surface of said one of said fin elements.

94. The heat sink of claim 77 wherein different ones of said fin elements are made of different materials.

95. The heat sink of claim 77 wherein one or more of said fin elements is made at least in part of a material selected from a group consisting of aluminum, copper, and indium.

96. A printed circuit board made of a nano-composite material that includes:
an electrically insulating base material; and
nanostructures incorporated into said base material,
wherein said nanostructures enhance thermal performance of the printed circuit board, relative to a printed circuit board made of the base material, in at least one respect but do not substantially enhance an electrical conductivity of the printed circuit board.

97. The printed circuit board of claim 96 wherein said enhanced thermal performance in said at least one respect includes a higher thermal conductivity.

98. The printed circuit board of claim 96 wherein said nanostructures have a higher thermal conductivity than said base material.

99. The printed circuit board of claim 96 wherein said nanostructures include nanotubes.

100. The printed circuit board of claim 99 wherein said nanotubes include a first group of nanotubes that are generally aligned with each other and oriented so as to define a thermal path through at least a first portion of said body.

101. The printed circuit board of claim 100 wherein said nanotubes further include a second group of nanotubes that are generally aligned with each other and oriented in a different direction from said first group of nanotubes.

102. The printed circuit board of claim 100 wherein said first group of nanotubes is arranged to underlie a device-mounting location on a first surface of said printed circuit board.

103. The printed circuit board of claim 99 wherein said nanotubes include boron nitride nanotubes.

104. The printed circuit board of claim 96 wherein said nanostructures include diamond nanocrystals.

105. The printed circuit board of claim 96 wherein said nanostructures include randomly oriented nanotubes.

106. An integrated circuit device comprising:
a device layer including a heat-generating circuit component,
wherein said device layer is formed of a nano-composite material that includes a base material and nanostructures incorporated into said base material, and
wherein said nanostructures enhance thermal performance of the integrated circuit device, relative to an integrated circuit device made of the base material, in at least one respect.

107. The integrated circuit device of claim 106 wherein said enhanced thermal performance in at least one respect includes a higher thermal conductivity.

108. The integrated circuit device of claim 106 wherein said nanostructures include nanotubes.

109. The integrated circuit device of claim 108, wherein said nanotubes include a first group of nanotubes that are generally aligned with each other and oriented so as to define a first thermal path through said portion of said device layer.

110. The integrated circuit device of claim 108 wherein said nanotubes further include a second group of nanotubes that are generally aligned with each other and oriented so as to define a second thermal path through at least a second portion of said device layer.

111. The integrated circuit device of claim 110 wherein said first group of nanotubes and said second group of nanotubes are oriented in different directions.

112. The integrated circuit device of claim 108 wherein said nanotubes include boron nitride nanotubes.

113. An integrated circuit device comprising:
a substrate layer formed of a semiconductor material;
a first film layer disposed on said substrate layer, said first film layer comprising first nanotubes; and
an active layer disposed on said first film layer, said active layer including at least one heat-generating circuit component,
wherein said first film layer provides a thermal path between said active layer and said substrate layer.

114. The integrated circuit device of claim 113 wherein said active layer is formed of a nano-composite material that includes a base semiconductor material and second nanotubes incorporated into at least one region of said base semiconductor material, and
wherein said second nanotubes are arranged to provide a thermal path through said at least one region.

115. The integrated circuit device of claim 114 wherein said second nanotubes are boron nitride nanotubes.

116. The integrated circuit device of claim 113, further comprising a second film layer disposed on a bottom surface of said substrate layer, said second film layer comprising second nanotubes.

117. A package for an integrated circuit device, the package including:
a section formed of a nano-composite material that includes a base material and nanostructures incorporated into said base material,
wherein said nanostructures enhance thermal performance of the package, relative to a package made of the base material, in at least one respect.

118. The package of claim 117 wherein said enhanced thermal performance in at least one respect includes an increased heat transfer rate between an inner surface of said package and an outer surface of said package.

119. The package of claim 117 wherein said nanostructures include nanotubes.

120. The package of claim 119 wherein said nanotubes include a group of nanotubes that are generally aligned with each other and oriented so as to define a thermal path through said section.

121. The package of claim 120, wherein said thermal path extends from an inner surface of the package toward an outer surface of the package.

122. An injection-molded plastic part, the part including:
at least one section formed of a nano-composite material that includes a plastic base material and nanostructures incorporated into said plastic base material,
wherein said nanostructures enhance thermal performance of the plastic part, relative to a plastic part made of the plastic base material, in at least one respect.

123. The plastic part of claim 122 wherein said enhanced thermal performance in at least one respect includes a higher heat dissipation rate.

124. The plastic part of claim 122 wherein said nanostructures include nanotubes.

125. The plastic part of claim 122 wherein said nanotubes include a group of nanotubes that are generally aligned with each other and oriented so as to define a thermal path through said section.

126. The package of claim 125, wherein said thermal path extends from an inner surface of the package toward an outer surface of the package.

127. The plastic part of claim 122 wherein said part is shaped as a component of a laptop computer case.

128. The plastic part of claim 122 wherein said part is shaped as a component of a housing for a telephone handset.

129. The plastic part of claim 122 wherein said part is shaped as a component of a housing for a personal digital assistant.
